(19) United States
(12) Patent Application Publication
(10) Pub. No.: US 2017/0137933 A1
(43) Pub. Date: May 18, 2017

(54) VAPOR DEPOSITION APPARATUS AND VAPOR DEPOSITION METHOD FOR FLEXIBLE SUBSTRATE

(71) Applicant: BOE Technology Group Co., Ltd., Beijing (CN)

(72) Inventor: Dejiang Zhao, Beijing (CN)

(21) Appl. No.: 15/105,404

(22) PCT Filed: Sep. 15, 2015
(86) PCT No.: PCT/CN2015/089597

§ 371 Date: Jun. 16, 2016

(30) Foreign Application Priority Data
May 15, 2015 (CN) 201510250246.9

(51) Int. Cl. C23C 14/56; C23C 16/54

(52) U.S. Cl. CPC C23C 14/562; C23C 16/545

(57) ABSTRACT

The invention provides a vapor deposition apparatus and a vapor deposition method for flexible substrate, and pertains to the technical field of display, which can solve the problem that an existing method for subjecting a flexible substrate to vapor deposition is prone to damage a structure formed by vapor deposition already on a flexible substrate. The vapor deposition apparatus for flexible substrate comprises at least two reels used for winding and fixing a flexible substrate; and a wire source unit located at one side of the flexible substrate between the two reels and used for subjecting the flexible substrate between the two reels to vapor deposition. In this vapor deposition apparatus for flexible substrate, the flexible substrate is wound and fixed with the reels and does not need to be peeled off from a glass substrate after vapor deposition is complete, and thus the structure formed by vapor deposition on the flexible substrate will not be damaged. By means of the vapor deposition apparatus for flexible substrate, it is possible to achieve continuous operation and improve production efficiency. The vapor deposition apparatus for flexible substrate is suitable for vapor deposition of all types of flexible substrates.

### TECHNICAL FIELD

This present invention pertains to the technical field of display, and particularly to a vapor deposition apparatus and a vapor deposition method for a flexible substrate.

### BACKGROUND ART

The OLED display substrate has various advantages, such as self-luminescence, low drive voltage, high luminescence efficiency, short response time, high definition and contrast, wide view angle of near 180°, capability of realizing large-area full color display, etc. It is well considered as the most promising display substrate in the art. Compared to other types of display devices, one of the highlights of the OLED display substrate is that flexible display can be achieved. That is, a bendable flexible substrate is used to produce a lightweight, bendable, and portable flexible display device.

A flexible OLED display substrate comprises a thin-film transistor array formed on a flexible substrate and an anode of an OLED device controlled by the thin-film transistor array. The OLED device comprises the above-mentioned anode, a cathode, and an organic material layer between the anode and the cathode, wherein the cathode and the organic material layer are typically formed by a vapor deposition process.

Since the flexible substrate itself is soft, if the flexible substrate is directly subjected to vapor deposition, the position of the mask is prone to be dislocated and is difficult to be accurately controlled during the process for forming a thin-film transistor array and an anode (array process). In the prior art, in the manufacture of a flexible OLED display substrate, a flexible substrate is first fixed to a glass substrate and an array process is performed, a desired structure is then formed by vapor deposition thereon using a conventional OLED vapor deposition apparatus, and after an OLED device is accomplished, the flexible substrate is peeled off from the glass substrate by a technique of laser irradiation.

The inventor has found that the following problem is at least present in the prior art. Although the position of vapor deposition is accurate by performing vapor deposition with a conventional OLED vapor deposition apparatus and then peeling the flexible substrate off from the glass substrate, the flexible substrate has insufficient mechanical strength and bad stability, and the structure formed by vapor deposition on a flexible substrate is prone to be damaged in the process of peeling.

### SUMMARY

With respect to the problem that the existing method for subjecting a flexible substrate to vapor deposition is prone to damage a structure formed by vapor deposition already on a flexible substrate, an embodiment of the invention provides a vapor deposition apparatus for flexible substrate.

A technical solution that can be used for solving the technical problem of the invention is:

a vapor deposition apparatus for flexible substrate, comprising:

at least two reels used for winding and fixing a flexible substrate; and

a wire source unit located at one side of the flexible substrate between the two reels and used for subjecting the flexible substrate between the two reels to vapor deposition.

Preferably, the vapor deposition apparatus for flexible substrate further comprises a mask for defining a vapor deposition pattern on the flexible substrate.

Preferably, the mask is provided on the side face, which is to be subjected to vapor deposition, of the flexible substrate, and the flexible substrate and the mask are simultaneously wound on the reels.

Preferably, a mask unit is provided between the flexible substrate, which is between the two reels, and the wire source unit, and used for fixing the mask between the flexible substrate, which is between the two reels, and the wire source unit.

Preferably, the reels are used for driving the flexible substrate to rotate at a constant speed.

Preferably, the linear velocity at which the reels drive the flexible substrate to move is 0.005-0.05 m/s.

Preferably, a ferromagnetic material is provided on the side face, which is not to be subjected to vapor deposition, of the flexible substrate, and the vapor deposition apparatus for flexible substrate further comprises a magnetic attraction unit used for applying an attractive force to the flexible substrate between the two reels.

Preferably, a plurality of layers of the flexible substrate are wound on the reels, and gaps are provided between the layers of the flexible substrate.

Preferably, a plurality of projections are provided on peripheries in at least two different positions in the direction of the length of the reel, used for fixing the flexible substrate, and holes are provided in positions, which are on the flexible substrate and correspond to the projections.

Preferably, the gap is obtained by changing the circumferential size of the projections and the corresponding size of the holes.

More preferably, the circumferential size of the projection gradually decreases in the direction away from the surface of the reel, and along the running direction of the flexible substrate, the size of the hole on the flexible substrate corresponding to the projection on the reel used for the flexible substrate before vapor deposition gradually decreases, while the size of the hole corresponding to the projection on the reel used for the flexible substrate after vapor deposition gradually increases.

Preferably, the gap is obtained by changing the pitch between the holes.

Preferably, the holes on the flexible substrate comprise two groups of holes, which correspond to the projections on the two reels, respectively.

An embodiment of the invention also provides a vapor deposition method for a flexible substrate. This method performs vapor deposition by using the vapor deposition apparatus for flexible substrate described above, and the method comprises:

performing vapor deposition on the flexible substrate with the wire source unit in the process of transferring the flexible substrate from one reel to another by means of the rotation of the reels.

Preferably, the rotation may be continuous or stepwise.

Here, after the completion of the vapor deposition, either the reel may be directly replaced, or the flexible substrate on the reel may be removed, and a flexible substrate not subjected to vapor deposition is further wound. Either one flexible substrate may be wound and fixed on the reel, or a plurality of continuous flexible substrates may be wound and fixed on the reel. That is, flexible substrates to be subjected to vapor deposition are combined and bonded and then wound and fixed onto a reel. In this way, continuous operation can be achieved upon vapor deposition.

Embodiments of the invention may have the advantageous effects as follows.

In the vapor deposition apparatus for flexible substrate of an embodiment of the invention, the flexible substrate is wound and fixed with the reels and does not need to be peeled off from a glass substrate after vapor deposition is complete, and thus the structure formed by vapor deposition on the flexible substrate will not be damaged. By means of the vapor deposition apparatus for flexible substrate of an embodiment of the invention, it is possible to achieve continuous operation and improve production efficiency. The vapor deposition apparatus for flexible substrate of an embodiment of the invention is suitable for vapor deposition of all types of flexible substrates.

### DESCRIPTION OF DRAWINGS

FIG. 1 is a structural schematic diagram of the vapor deposition apparatus for flexible substrate of Example 2 of the invention;

FIG. 2 is a structural schematic diagram of the reels and the flexible substrate in the vapor deposition apparatus for flexible substrate of Example 2 of the invention;

FIG. 3 is a schematic diagram of a reel in the vapor deposition apparatus for flexible substrate of Example 2 of the invention;

FIG. 4 is a schematic diagram of a flexible substrate in the vapor deposition apparatus for flexible substrate of Example 2 of the invention;

FIG. 5 is another schematic diagram of a reel in the vapor deposition apparatus for flexible substrate of Example 2 of the invention; and

FIG. 6 is another schematic diagram of a flexible substrate in the vapor deposition apparatus for flexible substrate of Example 2 of the invention;

Herein, reference numerals are as follows: 10, flexible substrate; 101, hole; 11, reel; 12, projection; 21, wire source unit; 31, mask unit; 32, mask; 41, magnetic attraction unit; and 42, ferromagnetic material.

### DESCRIPTION OF EMBODIMENTS

In order to allow the person skilled in the art to understand the technical solution of the invention better, the invention will be further described in detail in conjunction with accompanying drawings and specific embodiments.

### Example 1

This Example provides a vapor deposition apparatus for flexible substrate, comprising:

at least two reels used for winding and fixing a flexible substrate; and

a wire source unit located at one side of the flexible substrate between the two reels and used for subjecting the flexible substrate between the two reels to vapor deposition.

In the vapor deposition apparatus for flexible substrate of this Example, the flexible substrate is wound and fixed with the reels and does not need to be peeled off from a glass substrate after vapor deposition is complete, and thus the structure formed by vapor deposition on the flexible substrate will not be damaged. By means of the vapor deposition apparatus for flexible substrate of this Example, it is possible to achieve continuous operation and improve production efficiency. The vapor deposition apparatus for flexible substrate of this Example is suitable for vapor deposition of all types of flexible substrates.

### Example 2

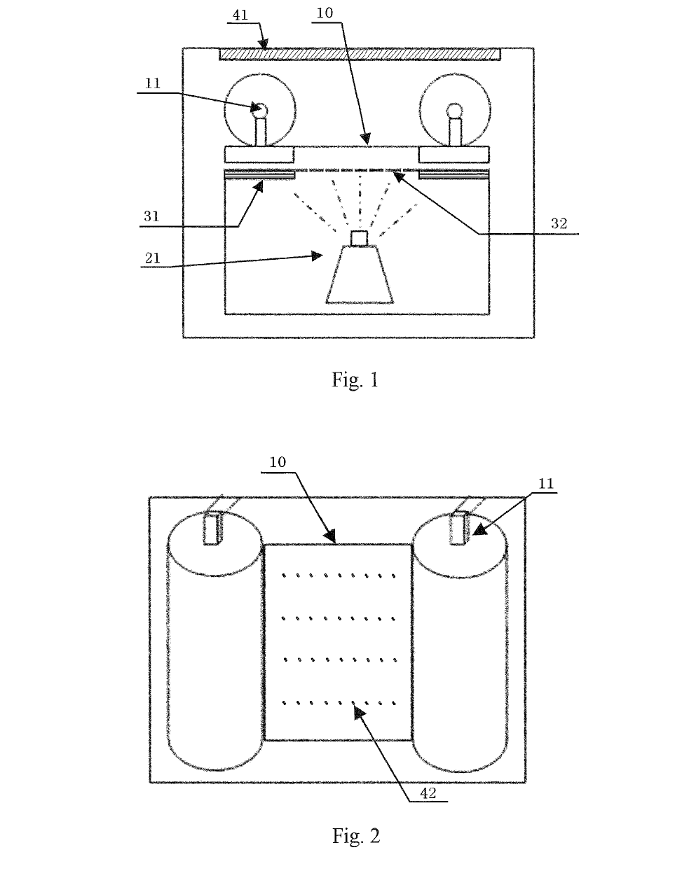

This Example provides a vapor deposition apparatus for flexible substrate, as shown in FIGS. 1-5, comprising:

at least two reels 11 used for winding and fixing a flexible substrate 10; and

a wire source unit 21 located at one side of the flexible substrate 10 between the two reels 11 and used for subjecting the flexible substrate 10 between the two reels 11 to vapor deposition.

That is, in this Example, firstly the flexible substrate 10 is wound onto the reel 11, the reel 11 starts to rotate during vapor deposition, the flexible substrate 10 to be subjected to vapor deposition is transferred between the two reels 11, and accurate vapor deposition on the flexible substrate 10 between the two reels 11 can be achieved once the wire source unit 21 is started.

Preferably, the flexible substrate 10 vapor deposition apparatus further comprises a mask 32 for defining a vapor deposition pattern on the flexible substrate 10.

That is, a mask 32 corresponding to the pattern to be formed by vapor deposition on the flexible substrate 10 may be provided according to the requirement of the process, and thereby the vapor deposition in the corresponding position can be achieved.

Preferably, the mask 32 is provided on the side face, which is to be subjected to vapor deposition, of the flexible substrate, and the flexible substrate 10 and the mask 32 are simultaneously wound on the reels 11.

As an embodiment of this Example, the mask 32 may be directly adhered to the flexible substrate 10 to be subjected to vapor deposition, and the mask 32 and the flexible substrate 10 are wound onto the reels 11 together. The pattern formed by vapor deposition on the flexible substrate 10 in this way is exactly the same as the mask 32, which is accurate without error.

Preferably, a mask unit 31 is provided between the flexible substrate 10, which is between the two reels 11, and the wire source unit 21, used for fixing the mask 32 between the flexible substrate 10, which is between the two reels 11, and the wire source unit 21.

That is to say, this Example may also employ another embodiment, in which the mask 32 and the flexible substrate 10 are not wound onto the reels 11 together, but the mask unit 31 is provided between the wire source unit 21 and the flexible substrate 10 to be subjected to vapor deposition, and the mask 32 is fixed on the mask unit 31. The raw material of the mask 32 is saved by means of this design, since the pattern to be formed by vapor deposition on the flexible substrate 10 is typically a regular pattern, and it is not needed to place the mask 32 corresponding to the entire flexible substrate 10 to the mask unit 31, while only the mask 32 corresponding to a regularly repeated pattern is needed to be fixed onto the mask unit 31. Further, when it is desired to form different patterns by vapor deposition on the flexible substrate 10, it may be convenient to replace the mask 32 on the mask unit 31.

Preferably, the reels 11 is used for driving the flexible substrate 10 to rotate at a constant speed.

That is, the rotation speed of the reels 11 may be controlled to allow for the continuous operation and work of the reels 11. Here, when the mask 32 and the flexible substrate 10 are wound onto the reel together, the wire source unit 21 may be always in a running state, while the reels 11 only need to rotate at a constant speed. When the mask 32 is provided on the mask unit 31 between the wire source unit 21 and the flexible substrate 10 to be subjected to vapor deposition, if the reels 11 rotate at a constant speed, switch-on and switch-off of the wire source unit 21 is required to be controlled. Or, when the mask 32 is provided on the mask unit 31 between the wire source unit 21 and the flexible substrate 10 to be subjected to vapor deposition, a mode of motion at a non-uniform speed, for example a stepwise mode, may be used. That is, a section of the flexible substrate 10 is moved to the mask 32 and then the movement is stopped and vapor deposition is performed, and the next section of the flexible substrate 10 is further moved to the mask 32 after the completion of the vapor deposition.

Preferably, the linear velocity at which the reels 11 drive the flexible substrate 10 to move is 0.005-0.05 m/s.

Preferably, a ferromagnetic material 42 is provided on the side face, which is not to be subjected to vapor deposition, of the flexible substrate 10, and the vapor deposition apparatus for flexible substrate further comprises a magnetic attraction unit 41 used for applying an attractive force to the flexible substrate 10 between the two reels 11.

That is to say, the ferromagnetic material 42 is adhered to the back side of the flexible substrate 10. For example, as shown in FIG. 2, the magnetic attraction unit 41 is provided above the back side of the flexible substrate 10. In this way, the magnetic attraction unit 41 will generate a magnetically attractive force to the ferromagnetic material 42 on the back side of the flexible substrate 10, so as to prevent the flexible substrate 10 from sagging due to gravity.

Preferably, a plurality of layers of the flexible substrate 10 are wound on the reels 11, and gaps are provided between the layers of the flexible substrate 10.

That is, the flexible substrate 10 is not excessively tightly wound onto the reel 11, and some gaps are left between wound layers. In this way, the friction or movement of the thin-film transistor on the flexible substrate 10 can be prevented.

Preferably, a plurality of projections 12 are provided on peripheries in at least two different positions in the direction of the length of the reel, used for fixing the flexible substrate 10, and holes 101 are provided in positions, which are on the flexible substrate 10 and correspond to the projections 12.

That is to say, the gaps between the layers of the flexible substrate 10 are ensured by means of the match relation between the projections 12 and the holes 101.

Preferably, the gap is obtained by changing the circumferential size of the projections and the corresponding size of the holes. For example, when the circumferential size of the projection decreases form the base, the flexible substrate having a portion with larger holes may fall down to the base of the projection, while the flexible substrate having a portion with smaller holes may only fall down to the middle part of the projection, such that the gaps between the layers of the wound flexible substrate are ensured.

Preferably, the circumferential size of the projection 12 gradually decreases in the direction away from the surface of the reel 11, and along the running direction of the flexible substrate 10, the size of the hole 101 on the flexible substrate 10 corresponding to the projection on the reel used for the flexible substrate before vapor deposition gradually decreases, while the size of the hole 101 corresponding to the projection on the reel used for the flexible substrate after vapor deposition gradually increases.

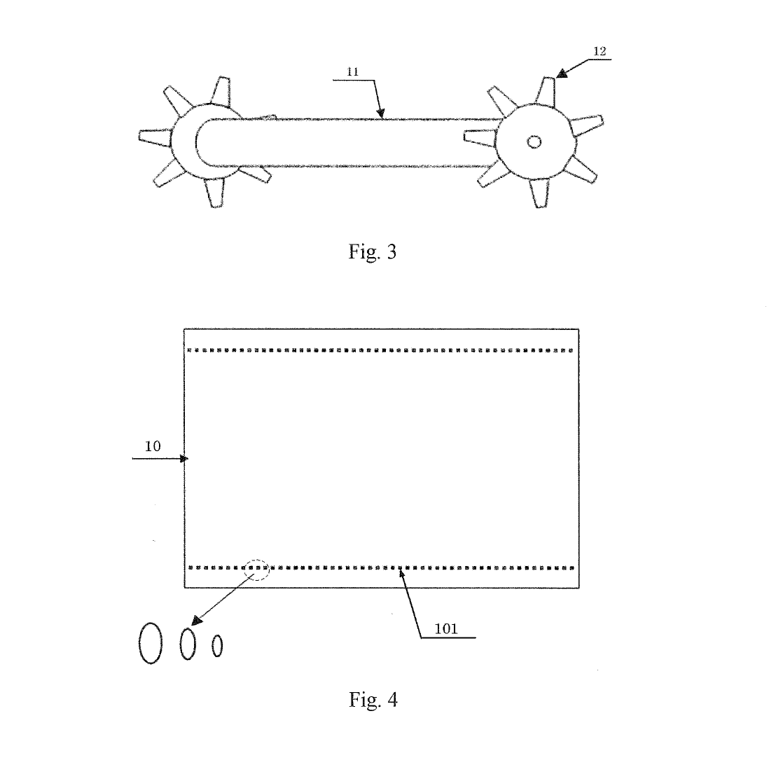

That is, as shown in FIGS. 3 and 4, two circles of truncated cones are uniformly provide on the periphery of the reel and holes 101 are correspondingly provided on the flexible substrate, and the size of the hole 101 varies with the size of the cross section of the truncated cone. In this way of design, the gaps between the layers of the wound flexible substrate 10 may be ensured. For the purpose of clarity, FIG. 4 only shows an enlarged view of a group of holes 101, which is, for example, used for a flexible substrate 10 moving from the left to the right; the flexible substrate 10 also has another group of holes 101 having reversed size order, since it is required that the flexible substrate 10 which arrives early at an destination reel falls down to the bases of the projections of the destination reel and the substrate which arrives late fails to fall down to the base.

Of course, if the product after the completion of the vapor deposition has a mechanical property allowing for tight winding, tight winding may also be achieved without projections on the destination reel.

Also preferably, the gap is obtained by changing the pitch between the holes.

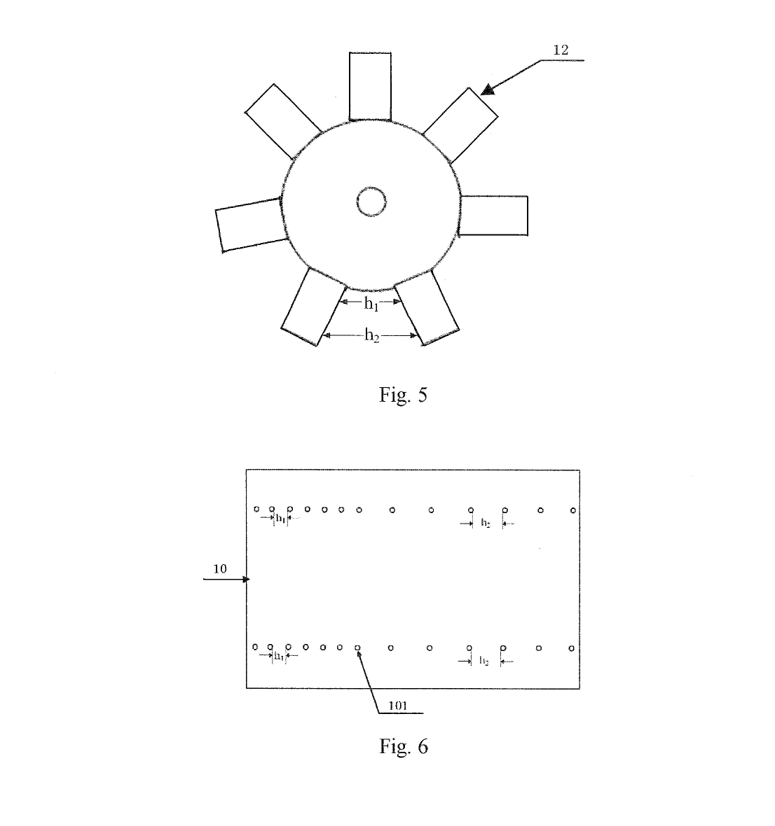

For example, as another embodiment of the Example of the invention, the projection 12 may also be provided as a cylindrical shape. As shown in FIGS. 5 and 6, the gaps of the layers of the wound flexible substrate 10 is controlled by defining the pitches between the holes 101, wherein the pitches h₁ and h₂ between the holes 101 are correspondingly the same as the pitches h₁ and h₂ of the adjacent projections 12. Similarly to those described above, for the purpose of clarity, FIG. 6 only shows holes 101 corresponding to one reel, which is a starting reel here, wherein the flexible substrate 10 moves from the left to the right. When the projection on the destination reel also has the same cylindrical shape and on the destination reel the gaps are still required to be maintained, another group of holes are provided on the flexible substrate, wherein the distance between the holes which arrive early at the destination reel is, for example smaller h₁, while the distance between the holes which arrive late at the destination reel is, for example larger h₂.

Preferably, the holes on the flexible substrate comprise two groups of holes, which correspond to the projections on the two reels, respectively. One group is used for ensuring the gaps on the starting reel, while the other group is used for ensuring the gaps on the destination reel. The above function may also be achieved with the same group of holes. Those described above are merely a few examples for ensuring the distance between layers by means of the principle of the projection and the hole matched therewith, and the person skilled in the art may design other particular structures, which are not described in detail herein, with this principle.

Clearly, a number of variations can be made to specific embodiments of the above Examples. For example, the reel and the flexible substrate are not in uniform motion, but are stepwise, wherein the flexible substrate is driven by the reel to a position above the wire source unit and stops, the wire source unit is then started and vapor deposition is performed, and after the completion of the vapor deposition, the next flexible substrate is conveyed for vapor deposition.

### Example 3

This Example provides a vapor deposition method for a flexible substrate, which performs vapor deposition by using the vapor deposition apparatus for flexible substrate of Example 2.

In particular, vapor deposition on the flexible substrate with the wire source unit is performed during the process of transferring the flexible substrate from one reel to another by means of the rotation of the reel. The mask and the specific form of the mask are optional. The rotation of the reel may be continuous or stepwise.

It can be understood that the above embodiments are merely exemplary embodiments used for illustrating the principle of the invention. However, the invention is not limited thereto. With respect to those of ordinary skill in the art, various variations and modifications can be made without departing from the spirit and the substance of the invention. These variations and modifications are also considered as the scope protected by the invention.

1. A vapor deposition apparatus for flexible substrate, wherein the vapor deposition apparatus for flexible substrate comprises:
at least two reels used for winding and fixing a flexible substrate; and
a wire source unit located at one side of the flexible substrate between the two reels and used for subjecting the flexible substrate between the two reels to vapor deposition,
and wherein a plurality of layers of the flexible substrate are wound on the reels, and gaps are provided between the layers of the flexible substrate.

2. The vapor deposition apparatus for flexible substrate according to claim 1, wherein the vapor deposition apparatus for flexible substrate further comprises a mask for defining a vapor deposition pattern on the flexible substrate.

3. The vapor deposition apparatus for flexible substrate according to claim 2, wherein the mask is provided on the side face, which is to be subjected to vapor deposition, of the flexible substrate, and the flexible substrate and the mask are simultaneously wound on the reels.

4. The vapor deposition apparatus for flexible substrate according to claim 2, wherein a mask unit is provided between the flexible substrate, which is between the two reels, and the wire source unit, and used for fixing the mask between the flexible substrate, which is between the two reels, and the wire source unit.

5. (canceled)

6. (canceled)

7. The vapor deposition apparatus for flexible substrate according to claim 1, wherein a ferromagnetic material is provided on the side face, which is not to be subjected to vapor deposition, of the flexible substrate, and the vapor deposition apparatus for flexible substrate further comprises a magnetic attraction unit used for applying an attractive force to the flexible substrate between the two reels.

8. (canceled)

9. The vapor deposition apparatus for flexible substrate according to claim 1, wherein a plurality of projections are provided on peripheries in at least two different positions in the direction of the length of the reel, used for fixing the flexible substrate, and holes are provided in positions, which are on the flexible substrate and correspond to the projections.

10. The vapor deposition apparatus for flexible substrate according to claim 9, wherein the gap is obtained by changing the circumferential size of the projections and the corresponding size of the holes.

11. The vapor deposition apparatus for flexible substrate according to claim 10, wherein the circumferential size of the projection gradually decreases in the direction away from the surface of the reel, and along the running direction of the flexible substrate, the size of the hole on the flexible substrate corresponding to the projection on the reel used for the flexible substrate before vapor deposition gradually decreases, while the size of the hole corresponding to the projection on the reel used for the flexible substrate after vapor deposition gradually increases.

12. The vapor deposition apparatus for flexible substrate according to claim 9, wherein the gap is obtained by changing the pitch between the holes.

13. The vapor deposition apparatus for flexible substrate according to claim 9, wherein the holes on the flexible substrate comprise two groups of holes, which correspond to the projections on the two reels, respectively.

14. A vapor deposition method for a flexible substrate, wherein vapor deposition is performed by using the vapor deposition apparatus for flexible substrate of claim 1, and the method comprises:
performing vapor deposition on the flexible substrate with the wire source unit in the process of transferring the flexible substrate from one reel to another by means of the rotation of the reels.

15. The method of claim 14, wherein the rotation may be continuous or stepwise.

16. The method of claim 14, wherein the reels drive the flexible substrate to rotate at a constant speed.

17. The method of claim 16, wherein the linear velocity at which the reels drive the flexible substrate to move is 0.005-0.05 m/s.
